(19) United States
(12) Patent Application Publication
(10) Pub. No.: US 2011/0108111 A1
(43) Pub. Date: May 12, 2011

(54) PHOTOELECTRIC CONVERSION DEVICE

(76) Inventors: Nam-Choul Yang, Suwon-si (KR); Hyun-Chul Kim, Suwon-si (KR); Moon-Sung Kang, Suwon-si (KR)

(21) Appl. No.: 12/784,340

(22) Filed: May 20, 2010

Related U.S. Application Data
(60) Provisional application No. 61/259,109, filed on Nov. 6, 2009.

(51) Int. Cl. H01L 31/02

(52) U.S. Cl. 136/259; 257/E31.11

(57) ABSTRACT

A photoelectric conversion device that may effectively prevent an electrolyte from leaking and have a high durability. The photoelectric conversion device includes a first substrate and a second substrate spaced from the first substrate with a space therebetween. The first substrate has an inlet from a side of the first substrate opposite a side facing the second substrate, and the inlet extends through the first substrate to the space between the first and second substrates. A filling material substantially fills at least a portion of the inlet. A cap is on the first substrate and covers the inlet. The filling material isolates the cap from the space such that the space is double sealed from the side of the first substrate opposite the side facing the second substrate.

### CROSS-REFERENCE TO RELATED APPLICATIONS

This application claims priority to and the benefit of U.S. Provisional Application No. 61/259,109, filed on Nov. 6, 2009, in the United States Patent and Trademark Office, the disclosure of which is incorporated herein in its entirety by reference.

### BACKGROUND

1. Field

Aspects of one or more embodiments of the present invention relate to a photoelectric conversion device.

2. Description of Related Art

Extensive research has been conducted on photoelectric conversion devices that convert light into electrical energy. From among such devices, solar cells have attracted much attention as alternative energy sources to fossil fuels.

Wafer-based crystalline silicon solar cells using a P-N semiconductor junction have been widely used. However, the manufacturing cost of wafer-based crystalline silicon solar cells is high because they are formed of a high purity semiconductor material.

Unlike silicon solar cells, dye-sensitized solar cells include a photosensitive dye that receives visible light and generates excited electrons, a semiconductor material that receives the excited electrons, and an electrolyte that reacts with electrons returning from an external circuit. Since dye-sensitized solar cells have much higher photoelectric conversion efficiency than other conventional solar cells, the dye-sensitized solar cells are considered as the next generation solar cells.

### SUMMARY

Aspects of one or more embodiments of the present invention relate to a photoelectric conversion device that may effectively prevent an electrolyte from leaking and have a high durability.

According to an embodiment of the present invention, a photoelectric conversion device includes: a first substrate and a second substrate spaced from the first substrate with a space therebetween, the first substrate having an inlet from a side of the first substrate opposite a side facing the second substrate, the inlet extending through the first substrate to the space between the first and second substrates; a filling material located in the inlet to substantially fill at least a portion of the inlet; and a cap on the first substrate and covering the inlet. The filling material isolates the cap from the space such that the space is double sealed from the side of the first substrate opposite the side facing the second substrate.

A side of the filling material facing the cap may have a concave surface.

The photoelectric conversion device may further include an inert gas in a portion of the inlet between the cap and the filling material.

A portion of the inlet proximate to the space may be narrower than a portion of the inlet distal to the space.

The photoelectric conversion device may further include a sealing material between the cap and the first substrate.

At least a portion of the inlet may have a substantially cylindrical shape.

The filling material may include a thermosensitive material having variable mobility according to temperature.

The filling material may have mobility when the temperature is between about 80 degree C. and about 180 degree C.

The filling material may be formed from a photosensitive material.

The filling material may include a resin-based material.

The filling material may further include an inorganic filler including a material selected from the group consisting of Al2O3, SiO2, and TiO2.

The filling material may include a material selected from the group consisting of ethyl vinyl acetate, polyolefine, silicon, and ionomer.

According to another embodiment of the present invention, a photoelectric conversion device includes: a first substrate and a second substrate spaced from the first substrate with a space therebetween, the first substrate having an inlet from a side of the first substrate opposite a side facing the second substrate, the inlet extending through the first substrate to the space between the first and second substrates; a filling material having a first portion located in the inlet and a second portion in the space, a width of the second portion being wider than that of the inlet; and a cap on the first substrate and covering the inlet. The filling material isolates the cap from the space such that the space is double sealed from the side of the first substrate opposite the side facing the second substrate.

The photoelectric conversion device may further include an inert gas in a portion of the inlet between the cap and the filling material.

A side of the filling material facing the cap may have a concave surface.

A portion of the inlet proximate to the space may be narrower than a portion of the inlet distal to the space.

The filling material may include a thermosensitive material having variable mobility according to temperature.

The filling material may have mobility when the temperature is between about 80 degree C. and about 180 degree C.

The filling material may be formed from a photosensitive material.

The filling material may include a resin-based material.

The filling material may further include an inorganic filler comprising a material selected from the group consisting of Al2O3, SiO2, and TiO2.

The filling material may include a material selected from the group consisting of ethyl vinyl acetate, polyolefine, silicon, and ionomer.

According to the above-described exemplary embodiments of the present invention, a photoelectric conversion device may effectively prevent an electrolyte from leaking and have a high durability. According to the exemplary embodiments, a filling material is injected into the photoelectric conversion device through an electrolyte inlet so that external harmful substances, such as oxygen or water, are blocked, thereby effectively preventing electrolyte from deteriorating or leaking. Also, by using a cap member that seals the electrolyte inlet, a double sealing structure is formed, thereby increasing a sealing performance of the photoelectric conversion device.

### BRIEF DESCRIPTION OF THE DRAWINGS

FIG. 1 is an exploded perspective view of a photoelectric conversion device according to an embodiment of the present invention;

FIG. 2 is a cross-sectional view taken along the line II-II of FIG. 1;

FIG. 3 is a cross-sectional view taken along the line III-III of FIG. 1 for illustrating a sealing structure of an electrolyte inlet according to an embodiment of the present invention;

FIG. 4 is a cross-sectional view for illustrating a sealing structure of an electrolyte inlet according to another embodiment of the present invention;

FIG. 5 is a top view of the sealing structure of the electrolyte inlet of FIG. 4;

FIG. 6 is a cross-sectional view for illustrating a sealing structure of an electrolyte inlet according to another embodiment of the present invention; and

FIGS. 7A, 7B, 7C, 7D, 7E, 7F, 7G, and 7H are cross-sectional views for illustrating processes of manufacturing a photoelectric conversion device, according to an embodiment of the present invention.

### EXPLANATION OF REFERENCE NUMERALS DESIGNATING SOME ELEMENTS OF THE DRAWINGS

110: light receiving substrate
110′: electrolyte inlet
111, 121: transparent conductive layer
113,123: grid electrode
114: photoelectrode
115, 125: protective layer
116: semiconductor layer
118, 128: functional layer
120: counter substrate
122: catalyst layer
124: counter electrode
130: sealing member
150: electrolyte layer
160: cap member
161: sealing material
170, 270, 370: filling material
170a: upper surface of filling material
175, 375: rare gas
180: external circuit
190: wire
270a, 370a: first portion of filling material
270b, 370b: second portion of filling material
G: substrate gap

### DETAILED DESCRIPTION

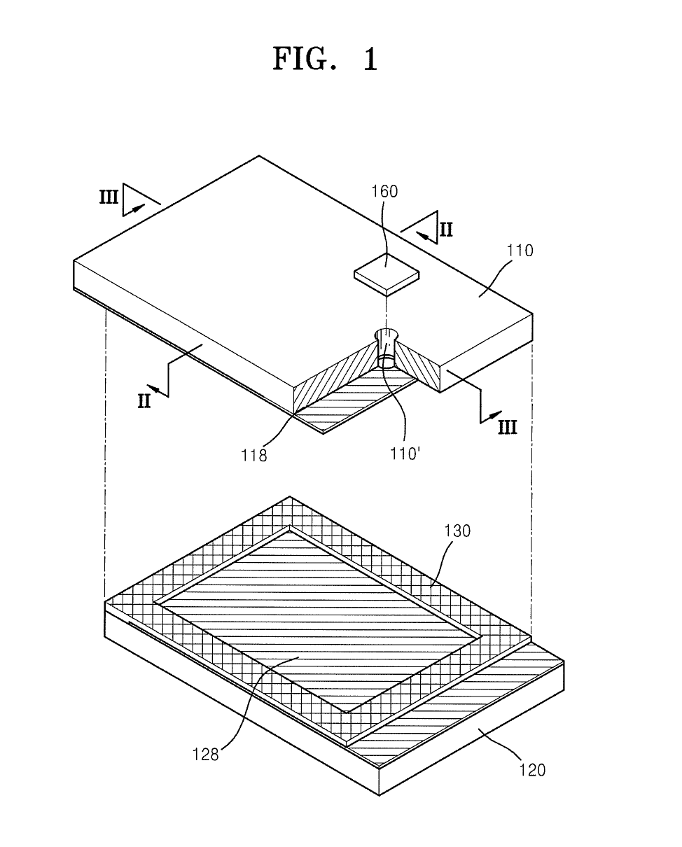

Exemplary embodiments of the present invention will now be described with reference to the attached drawings. FIG. 1 is an exploded perspective view of a photoelectric conversion device according to an embodiment of the present invention. Referring to FIG. 1, a light receiving substrate 110, on which a functional layer 118 is formed, and a counter substrate 120, on which a functional layer 128 is formed, face each other. A sealing member 130 is disposed between the light receiving substrate 110 and the counter substrate 120 along edges of the two substrates to attach them to each other. An electrolyte is injected into the photoelectric conversion device through an electrolyte inlet 110′ formed in the light receiving substrate 110. The sealing member 130 seals the electrolyte in the photoelectric conversion device so that the electrolyte does not leak to the outside.

The functional layers 118 and 128 formed on the light receiving substrate 110 and the counter substrate 120 include a semiconductor layer for generating electrons excited by irradiated light and electrodes for collecting and discharging the generated electrons. For example, one end of the electrode structure of the functional layers 118 and 128 may extend to the outside of the sealing member 130 to be connected with an external circuit located on the outside.

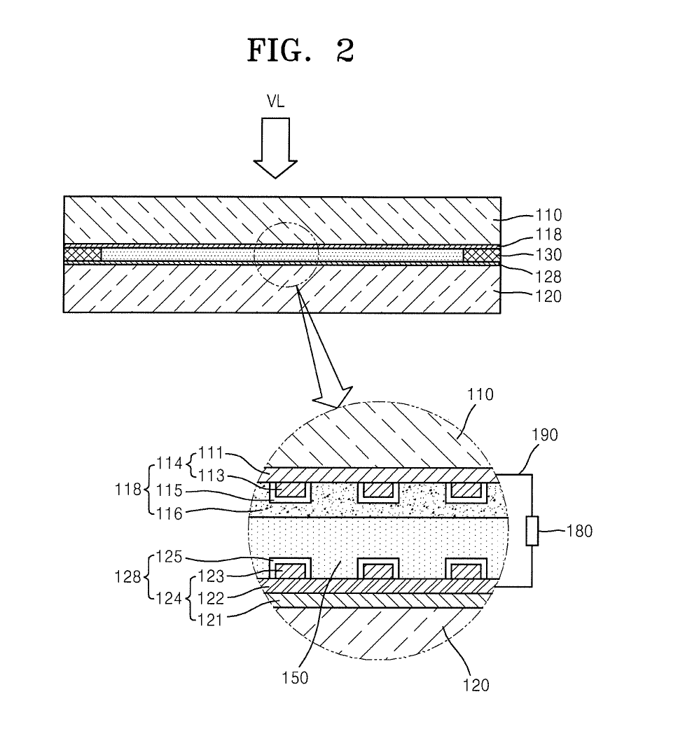

FIG. 2 is a cross-sectional view taken along the line II-II of FIG. 1. Referring to FIG. 2, a light receiving substrate 110, on which a photoelectrode 114 is formed, and a counter substrate 120, on which a counter electrode 124 is formed, face each other. A semiconductor layer 116 is formed on the photoelectrode 114. A photosensitive dye is absorbed into the semiconductor layer 116 and is excited when irradiated by light VL. An electrolyte 150 is injected between the semiconductor layer 116 and the counter electrode 124. For example, the photoelectrode 114 and the semiconductor layer 116 correspond to the functional layer 118 adjacent to the light receiving substrate 110, and the counter electrode 124 corresponds to the functional layer 128 adjacent to the counter substrate 120.

The light receiving substrate 110 and the counter substrate 120 are attached to each other using the sealing member 130 so that a space is formed therebetween. The sealing member 130 surrounds and seals the space formed between the light receiving substrate 110 and the counter substrate 120 so that the electrolyte 150 does not leak to the outside.

The photoelectrode 114 and the counter electrode 124 are electrically connected to each other by a wire 190 through an external circuit 180. In a module in which a plurality of photoelectric conversion devices are connected in series or in parallel, the photoelectrodes 114 and the counter electrodes 124 may be connected to each other in series or in parallel, and both ends of connected portions may be connected to the external circuit 180.

The light receiving substrate 110 may be formed of a transparent material, for example, a material having a high light transmittance. For example, the light receiving substrate 110 may be a glass substrate or a resin film substrate. Since a resin film is typically flexible, the resin film may be applied to devices requiring flexibility.

The photoelectrode 114 may include a transparent conductive layer 111 and a grid electrode 113 that is formed in a mesh-fashion on the transparent conductive layer 111. The transparent conductive layer 111 may be formed of a material having transparency and electrical conductivity, for example, a transparent conductive oxide (TCO) such as indium tin oxide (ITO), fluorine tin oxide (FTO), or antimony-doped tin oxide (ATO). The grid electrode 113 reduces the electrical resistance of the photoelectrode 114, and functions as a collector wire that collects electrons generated by photoelectric conversion and provides a current path having a low resistance. For example, the grid electrode 113 may be formed of a metal material having a high electrical conductivity, such as gold (Au), silver (Ag), or aluminum (Al), and may be patterned in a mesh fashion.

The photoelectrode 114 functions as a negative electrode of the photoelectric conversion device and may have a high aperture ratio. Since light VL incident through the photoelectrode 114 excites the photosensitive dye absorbed into the semiconductor layer 116, the photoelectric conversion efficiency may be improved when the amount of incident light VL is increased.

A protective layer 115 may be further formed on an outer surface of the grid electrode 113. The protective layer 115 prevents the grid electrode 113 from being damaged, for example, from being eroded, when the grid electrode 113 contacts and reacts with the electrolyte 150. The protective layer 115 may be formed of a material that does not react with the electrolyte 150, for example, a curable resin material.

The semiconductor layer 116 may be formed of a suitable semiconductor material including, for example, a material selected from the group consisting of cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si), and chromium (Cr). The semiconductor material may be a metal oxide, for example, including one or more of the metals listed above. The semiconductor layer 116 may increase the photoelectric conversion efficiency by absorbing the photosensitive dye. For example, the semiconductor layer 116 may be formed by coating a paste formed of semiconductor particles having a diameter of 5 to 1000 nm on the light receiving substrate 110 on which the photoelectrode 114 is formed and applying heat and pressure to a resultant structure.

The photosensitive dye, which is absorbed into the semiconductor layer 116, absorbs light VL passing through the light receiving substrate 110, so that electrons of the photosensitive dye are excited from a ground state. The excited electrons are transferred to a conduction band of the semiconductor layer 116 through electrical contact between the photosensitive dye and the semiconductor layer 116, to the semiconductor layer 116, and to the photoelectrode 114, and are discharged to the outside through the photoelectrode 114, thereby forming a driving current for driving the external circuit 180.

For example, the photosensitive dye, which is absorbed into the semiconductor layer 116, may include molecules that absorb light VL to excite electrons so as to allow the excited electrons to be rapidly moved to the semiconductor layer 116. The photosensitive dye may be any one of liquid type, semi-solid type, and solid type photosensitive dyes. For example, the photosensitive dye absorbed into the semiconductor layer 116 may be a ruthenium-based photosensitive dye. The photosensitive dye may be absorbed into the semiconductor layer 116 by dipping the light receiving substrate 110 on which the semiconductor layer 116 is formed in a solution including the photosensitive dye.

The electrolyte 150 may be formed of a redox electrolyte including reduced/oxidized (R/O) couples. The electrolyte 150 may be formed of any one of solid type, gel type, and liquid type electrolytes.

The counter substrate 120 facing the light receiving substrate 110 may not be transparent. However, in order to increase photoelectric conversion efficiency, the counter substrate 120 may be formed of a transparent material so as to receive light VL on both sides of the photoelectric conversion device, and may be formed of the same material as that of the light receiving substrate 110. In one embodiment, when the photoelectric conversion device is installed as a part of a building integrated photovoltaic system (BIPV) in a structure, e.g., a window frame, both sides of the photoelectric conversion device may be transparent so that light VL introduced into the photoelectric conversion device is not being blocked.

The counter electrode 124 may include a transparent conductive layer 121 and a catalyst layer 122 formed on the transparent conductive layer 121. The transparent conductive layer 121 may be formed of a material having transparency and electrical conductivity, for example, a transparent conductive oxide such as ITO, FTO, or ATO. The catalyst layer 122 may be formed of a reduction catalyzing material for providing electrons to the electrolyte 150, for example, a metal such as platinum (Pt), gold (Ag), silver (Au), copper (Cu), or aluminum (Al), a metal oxide such as a tin oxide, or a carbon-based material such as graphite.

The counter electrode 124 functions as a positive electrode of the photoelectric conversion device, and also as a reduction catalyst for providing electrons to the electrolyte 150. The photosensitive dye absorbed into the semiconductor layer 116 absorbs light VL to excite electrons, and the excited electrons are discharged to the outside of the photoelectric conversion device through the photoelectrode 114. The photosensitive dye losing the electrons receive electrons generated by oxidization of the electrolyte 150 to be reduced again, and the oxidized electrolyte 150 is reduced again by electrons passing through the external circuit 180 and reaching the counter electrode 124, thereby completing the operation of the photoelectric conversion device.

The counter electrode 124 may include a grid electrode 123 formed on the catalyst layer 122. The grid electrode 123 reduces the electrical resistance of the counter electrode 124. The grid electrode 123 also collects electrons passing through the external circuit 180 and reaching the counter electrode 124 and provides a low resistant current path for providing the electrons to the electrolyte layer 150. For example, the grid electrode 123 may be formed of a metal material having a high electrical conductivity, such as gold (Ag), silver (Au), or aluminum (Al), and patterned in a mesh fashion.

A protective layer 125 may be further formed on an outer surface of the grid electrode 123. The protective layer 125 prevents the grid electrode 123 from being damaged, for example, being eroded, when the grid electrode 123 contacts and reacts with the electrolyte layer 150. The protective layer 125 may be formed of a material that does not react with the electrolyte layer 150, for example, a curable resin material.

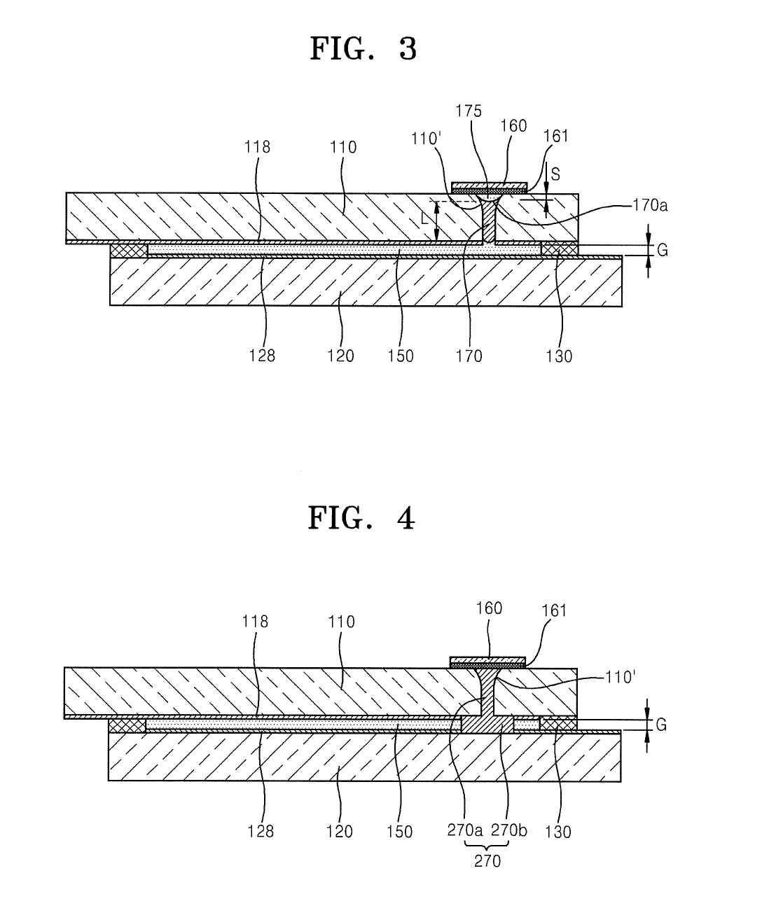

FIG. 3 is a cross-sectional view taken along the line III-III of FIG. 1, for illustrating a sealing structure of the electrolyte inlet 110′. The sealing member 130 is formed between edges of the light receiving substrate 110 and the counter substrate 120, and heat and pressure are applied to the light receiving substrate 110 and the counter substrate 120 to attach them to each other, thereby forming a substrate gap G between the light receiving substrate 110 and the counter substrate 120. The substrate gap G is filled with the electrolyte 150. For example, the electrolyte inlet 110′ for providing an injection path of the electrolyte 150 is formed in the light receiving substrate 110. The electrolyte inlet 110′ extends through the light receiving substrate 110 and is connected to the substrate gap G. For example, the electrolyte inlet 110′ may have a cylindrical shape.

A filling material 170 is filled along the electrolyte inlet 110′ to a length L. The filling material 170 blocks external harmful substances and is formed with sufficient length to prevent the electrolyte 150 from volatilizing or leaking. The filling material 170 has sufficient adhesion so as not to be separated from a wall surface of the electrolyte inlet 110′. The filling material 170 is sufficient to seal the substrate gap G, and besides may be chemically resistant to the electrolyte 150. The chemically resistant filling material 170 may effectively prevent the electrolyte 150 from leaking.

The filling material 170 may be a material having variable mobility according to the temperature of the environment. For example, the filling material 170 may be a material that has sufficient mobility to be injected into the substrate gap G in a high temperature environment, and hardens at a typical operating temperature to seal the electrolyte inlet 110′. After injection of the electrolyte 150 is finished, the filling material 170 at a suitable high temperature is injected into the electrolyte inlet 110′ using a pressurizing device, for example, a syringe or other suitable devices. The filling material 170 is hardened when it is cooled below a set temperature (e.g., a predetermined temperature) and firmly attached to the wall surface of the electrolyte inlet 110′.

Typically, since the photoelectric conversion device operates in a temperature range from about 50° C. to about 80° C., the filling material 170 may include a resin-based material having mobility in a temperature range from about 80° C. to about 180° C. In one embodiment, the filling material 170 may include ethyl vinyl acetate, polyolefine, silicon, ionomer, and a reformed resin-based material thereof, and the resin-based material may be impregnated with an inorganic filler such as SiO₂, Al₂O₃, or TiO₂.

As described above, the filling material 170 may include a thermosensitive material having variable mobility according to the temperature of the environment. Alternatively, the filling material 170 may include a photosensitive material having variable mobility according to light irradiation. An additional light curing treatment for hardening the filling material 170 may be performed, if necessary or desired.

The electrolyte inlet 110′ is sealed by a cap member 160. The cap member 160 may be formed of a material that does not transmit harmful substances such as oxygen or water, for example, a grass substrate or a metal thin plate. The cap member 160 may be attached to a peripheral region surrounding the circumference of the electrolyte inlet 110′ on the light receiving substrate 110 by a sealing material 161. The sealing material 161 may be a resin-based film, for example, an ionomer resin or a reformed polyolefine resin.

The cap member 160 and the filling material 170 filled in the electrolyte inlet 110′ form a double-sealing structure. Thus, the electrolyte 170 may be prevented from leaking through the double-sealing structure.

An inert gas 175 (e.g., a rare gas) is filled between the cap member 160 and the filling material 170. For example, a gap S may be formed between a concave upper surface 170a and the cap member 160, and the inert gas 175 is injected into the gap S, thus, preventing external harmful substances from entering through the gap S according to a negative pressure with respect to the external air pressure. Also, due to the chemical stability of the inert gas 175, the inert gas 175 does not affect durabilities of the sealing material 161 and the filling material 170 which are in contact with the inert gas 175. For example, after the injection of the filling material 170 is finished, the concave upper surface 170a of the filling material 170 may be concaved in the process for removing the excess filling material 170 on the light receiving substrate 110, or the concave upper surface 170a may be naturally formed through curing contraction.

FIG. 4 is a cross-sectional view for illustrating a sealing structure of an electrolyte inlet according to another embodiment of the present invention. Referring to FIG. 4, a filling material 270 filled in the electrolyte inlet 110′ extends along the substrate gap G. In other words, the filling material 270 is formed in a rivet shape, which includes a first portion 270a and a second portion 270b that bends from the first portion 270a and extends along the substrate gap G. The first portion 270a and the second portion 270b of the filling material 270 respectively seal the electrolyte inlet 110′ and a portion of the substrate gap G to block a leakage path of the electrolyte 150. The filling material 270 extends from the electrolyte inlet 110′ into the substrate gap G, thereby improving the sealing performance of the photoelectric conversion device. In one embodiment, as the filling material 270 extends to the substrate gap G, a contact area of the filling material 270 is increased and an adhesion strength of the filling material 270 is enhanced, thereby effectively preventing the electrolyte 150 from leaking.

At this point, the second portion 270b of the filling material 270 contacts the electrolyte 150 and a pressure distribution of the electrolyte 150 around the filling material 270 is approximately symmetrical about the electrolyte inlet 110′, thereby increasing the pressure resistance of the filling material 270.

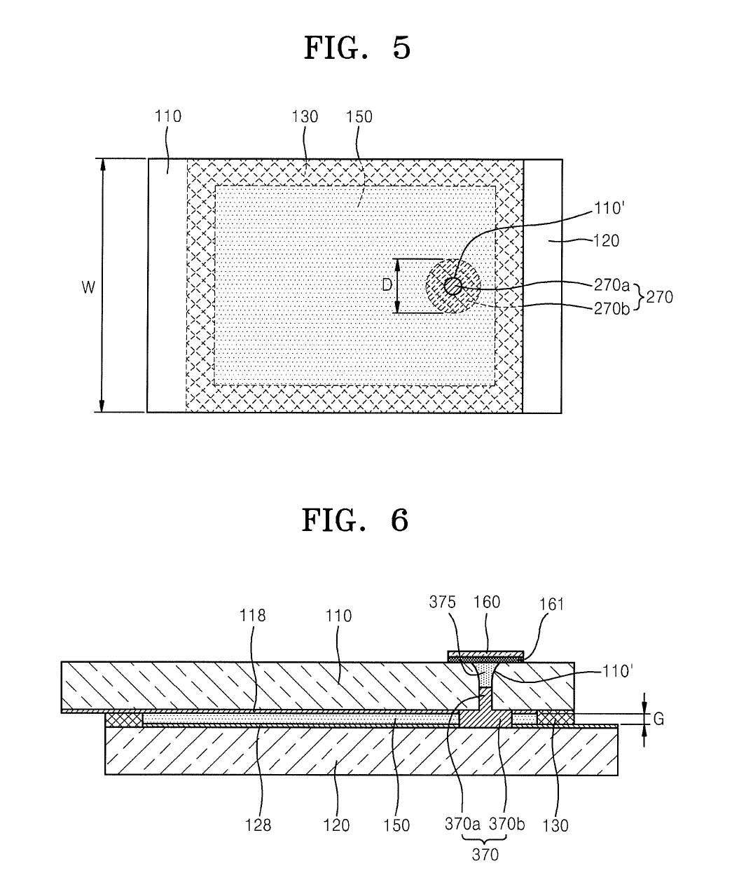

FIG. 5 is a top view of the sealing structure of the electrolyte inlet of FIG. 4, according to one embodiment of the present invention. Referring to FIG. 5, the first portion 270a of the filling material 270 filling the electrolyte inlet 110′ has a cylindrical shape, and the second portion 270b has a substantially circular plate shape. The second portion 270b may have a diameter D that is less than a width of the light receiving substrate 110 so that the second portion 270b does not partition the electrolyte 150 and allows the electrolyte 150 to flow around the second portion 270b. The second portion 270b of the filling material 270 forms a relatively wide contact area between the light receiving substrate 110 and the counter substrate 120, thereby exhibiting a high adhesion strength.

FIG. 6 is a cross-sectional view for illustrating a sealing structure of an electrolyte inlet according to another embodiment of the present invention. Referring to FIG. 6, a filling material 370 filled in the electrolyte inlet 110′ extends along a substrate gap G. In other words, the filling material 370 includes a first portion 370a filled in the electrolyte inlet 110′ and a second portion 370b that bends from the first portion 370a and extends along the substrate gap G. The filling material 370 may be injected into the electrolyte inlet 110′ using a pressurizing device, and the filling material 370 may be pushed out to a lower portion of the electrolyte inlet 110′ by the injection pressure to form a space between the cap member 160 and the filling material 370. An inert gas 375 (e.g., a rare gas) may be filled in the space between the cap member 160 and the filling material 370.

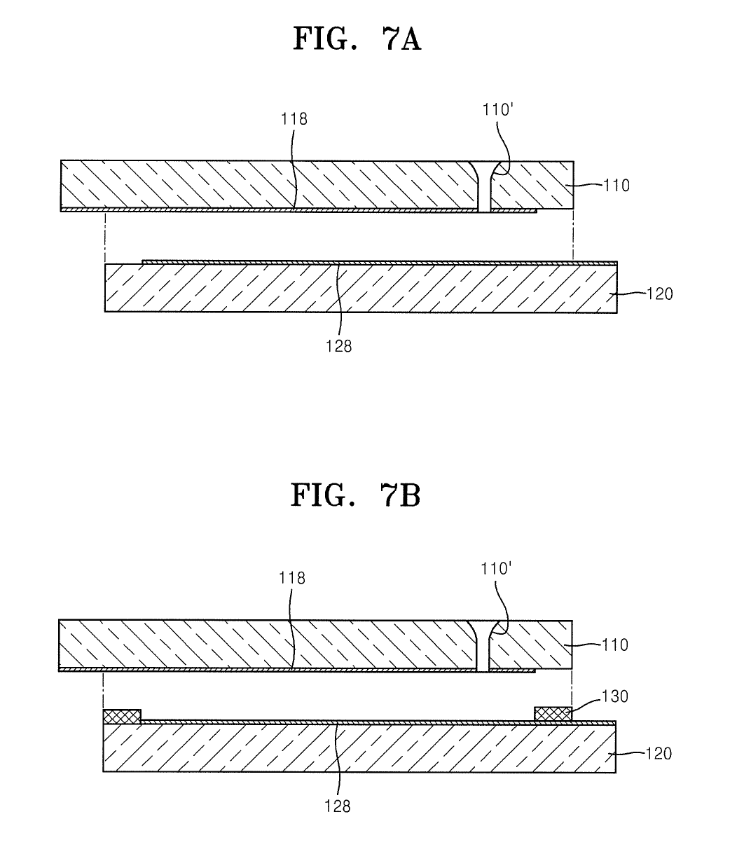

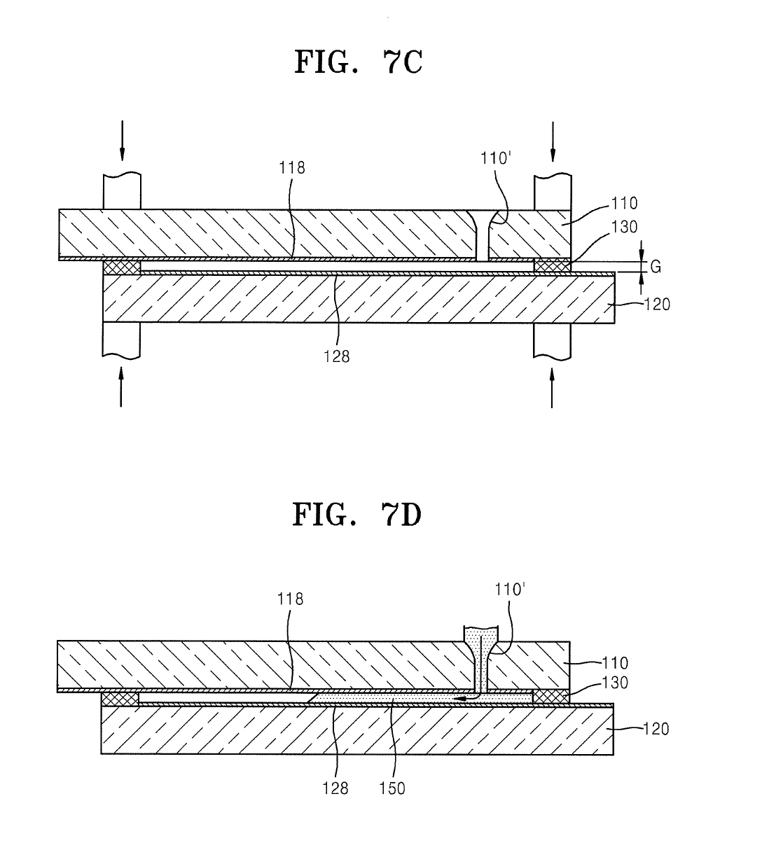

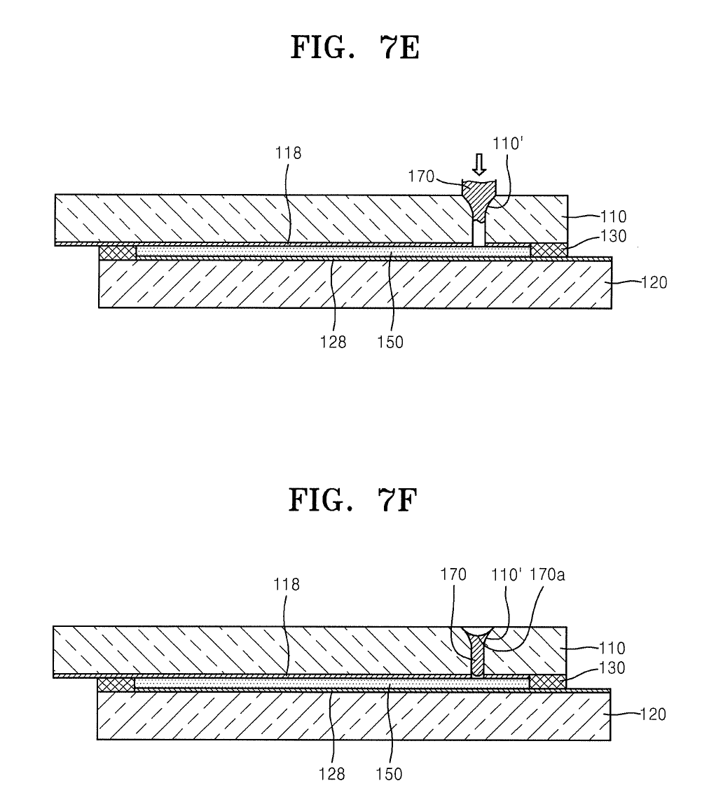

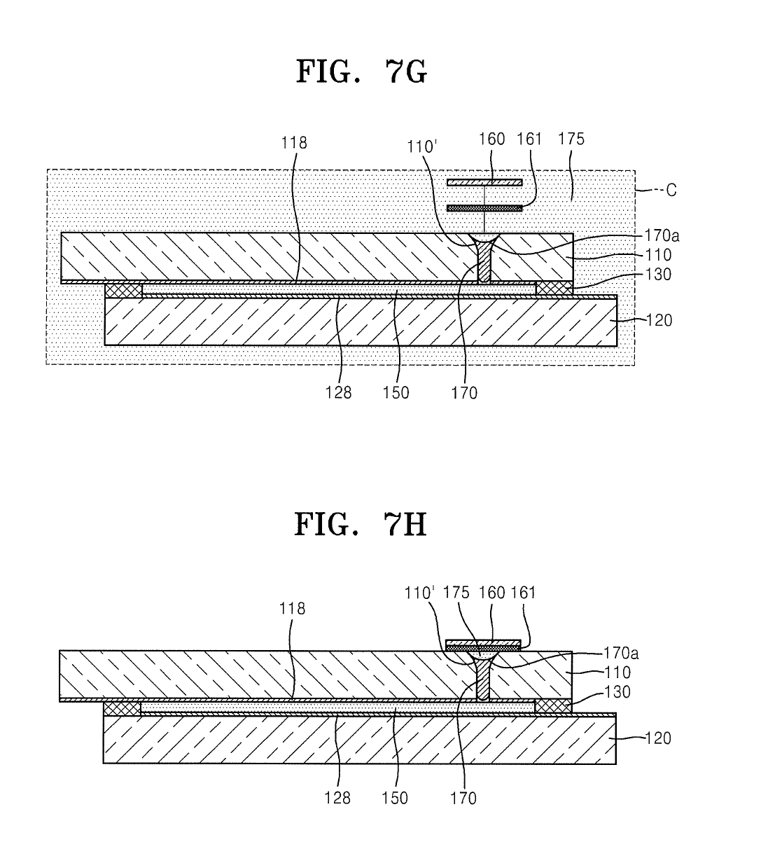

FIGS. 7A through 7H are cross-sectional views for illustrating processes of manufacturing a photoelectric conversion device, according to an embodiment of the present invention. Referring to FIG. 7A, a light receiving substrate 110 and a counter substrate 120 on which functional layers 118 and 128 for performing photoelectric conversion are respectively formed are prepared. The functional layers 118 and 128 include a semiconductor layer for receiving light and generating excited electrons and electrodes for receiving the generated electrons and discharging the electrons to the outside. In one embodiment, an electrolyte inlet 110′ for injecting an electrolyte is formed on at least any one of the light receiving substrate 110 and the counter substrate 120.

Next, referring to FIG. 7B, the light receiving substrate 110 and the counter substrate 120 are disposed to face each other, and a sealing member 130 is disposed between the light receiving substrate 110 and the counter substrate 120 along edges thereof. For example, referring to FIG. 7C, a thermal adhesive film used as the sealing member 130 is disposed along edges of the counter substrate 120, and heat and pressure are applied to attach the light receiving substrate 110 and the counter substrate 120 to each other, thereby forming a substrate gap G in which an electrolyte is to be filled.

Next, referring to FIG. 7D, the electrolyte 150 is injected under pressure into the substrate gap G through the electrolyte inlet 110′. Then, referring to FIGS. 7E and 7F, a filling material 170 is injected into the electrolyte inlet 110′ using a pressurizing device, for example, a syringe, and the electrolyte inlet 110′ may be sealed through a curing treatment if necessary or desired. For example, by controlling mobility and/or injection pressure of the filling material 170, the filling material 170 may extend from the electrolyte inlet 110′ to the substrate gap G. In one embodiment, a process for removing the excess filling material 170 remained on the light receiving substrate 110 may be performed, and in parallel with this process, a process for concaving an upper surface 170a of the filling material 170 may be performed.

Next, referring to FIG. 7G, the electrolyte inlet 110′ is sealed using a cap member 160. For example, the cap member 160 may be attached to a peripheral region surrounding the circumference of the electrolyte inlet 110′ on the light receiving substrate 110 via a sealing material 161. The sealing material 161 may be formed of a thermal adhesive film and is attached to the cap member 160 when appropriate pressure and temperature are applied. The cap member 160 may be sealed under an inert gas (e.g., a rare gas) atmosphere. For example, referring to FIG. 7G, the cap member 160 may be sealed in a sealed chamber C in which the inert gas 175 is filled under an appropriate pressure, so that the inert gas 175 may be naturally filled in a gap between the cap member 160 and the filling material 170.

While aspects of the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A photoelectric conversion device comprising:
a first substrate and a second substrate spaced from the first substrate with a space therebetween, the first substrate having an inlet from a side of the first substrate opposite a side facing the second substrate, the inlet extending through the first substrate to the space between the first and second substrates;
a filling material located in the inlet to substantially fill at least a portion of the inlet; and
a cap on the first substrate and covering the inlet,
wherein the filling material isolates the cap from the space such that the space is double sealed from the side of the first substrate opposite the side facing the second substrate.

2. The photoelectric conversion device of claim 1, wherein a side of the filling material facing the cap has a concave surface.

3. The photoelectric conversion device of claim 1, further comprising:
an inert gas in a portion of the inlet between the cap and the filling material.

4. The photoelectric conversion device of claim 1, wherein a portion of the inlet proximate to the space is narrower than a portion of the inlet distal to the space.

5. The photoelectric conversion device of claim 1, further comprising a sealing material between the cap and the first substrate.

6. The photoelectric conversion device of claim 1, wherein at least a portion of the inlet has a substantially cylindrical shape.

7. The photoelectric conversion device of claim 1, wherein the filling material comprises a thermosensitive material having variable mobility according to temperature.

8. The photoelectric conversion device of claim 1, wherein the filling material has mobility when the temperature is between about 80 degree C. and about 180 degree C.

9. The photoelectric conversion device of claim 1, wherein the filling material is formed from a photosensitive material.

10. The photoelectric conversion device of claim 1, wherein the filling material comprises a resin-based material.

11. The photoelectric conversion device of claim 10, wherein the filling material further comprises an inorganic filler comprising a material selected from the group consisting of Al2O3, SiO2, and TiO2.

12. The photoelectric conversion device of claim 1, wherein the filling material comprises a material selected from the group consisting of ethyl vinyl acetate, polyolefine, silicon, and ionomer.

13. A photoelectric conversion device comprising:
a first substrate and a second substrate spaced from the first substrate with a space therebetween, the first substrate having an inlet from a side of the first substrate opposite a side facing the second substrate, the inlet extending through the first substrate to the space between the first and second substrates;
a filling material having a first portion located in the inlet and a second portion in the space, a width of the second portion being wider than that of the inlet; and
a cap on the first substrate and covering the inlet, wherein the filling material isolates the cap from the space such that the space is double sealed from the side of the first substrate opposite the side facing the second substrate.

14. The photoelectric conversion device of claim 13, further comprising:
an inert gas in a portion of the inlet between the cap and the filling material.

15. The photoelectric conversion device of claim 13, wherein a side of the filling material facing the cap has a concave surface.

16. The photoelectric conversion device of claim 13, wherein a portion of the inlet proximate to the space is narrower than a portion of the inlet distal to the space.

17. The photoelectric conversion device of claim 13, wherein the filling material comprises a thermosensitive material having variable mobility according to temperature.

18. The photoelectric conversion device of claim 13, wherein the filling material has mobility when the temperature is between about 80 degree C. and about 180 degree C.

19. The photoelectric conversion device of claim 13, wherein the filling material is formed from a photosensitive material.

20. The photoelectric conversion device of claim 13, wherein the filling material comprises a resin-based material.

21. The photoelectric conversion device of claim 20, wherein the filling material further comprises an inorganic filler comprising a material selected from the group consisting of Al2O3, SiO2, and TiO2.

22. The photoelectric conversion device of claim 13, wherein the filling material comprises a material selected from the group consisting of ethyl vinyl acetate, polyolefine, silicon, and ionomer.
